(19) United States
(12) Patent Application Publication
(10) Pub. No.: US 2011/0241759 A1
(43) Pub. Date: Oct. 6, 2011

(54) OPERATING UNIT FOR ELECTRICAL APPLIANCES

(76) Inventor: Hans Schwaiger, Muenchen (DE)

(21) Appl. No.: 12/593,454

(22) PCT Filed: Jul. 31, 2009
(86) PCT No.: PCT/EP09/59924

§ 371 Date: Jun. 21, 2011

(30) Foreign Application Priority Data
Jul. 31, 2008 (DE) 202008010280.4
Aug. 5, 2008 (DE) 102008036442.8

(51) Int. Cl. H03K 17/96

(52) U.S. Cl. 327/517; 200/600

(57) ABSTRACT

The invention relates to an operating unit for operation of household appliances, especially for operation of a hob or a washing machine. In this connection, operating elements are arranged on an electrically conductive operating plate, by which they are capacitively coupled with a receiving device that is located in or at the household appliance. Transmission of the operation of the operating elements to the receiving device takes place by detection a load change in the receiving device, the load change being caused by the operating elements.

### FIELD OF THE INVENTION

The invention relates to an operating unit for operation of electric devices, especially of household appliances, such as a hob, a washing machine, a clothes drier, a dishwasher, or the like.

### STATE OF THE ART

A great variety of such operating units are known from the prior art. In particular, operating units for operation of stoves or hobs, respectively, or of washing machines are known as well.

In the field of hob operation, for instance, rotary switches for operation of a hob are known, which are arranged at the front of the stove. The rotary switches are connected to electronics, which adjusts the individual hobs according to the position of the rotary switches. Further, it is also known to arrange such rotary switches directly at the surface of the hot plate, especially in the case of hot plates that do not have their own front panel. This has the disadvantage, however, that the rotary switches occupy a certain space of the hot plate, and this space is then no longer available for cooking, i.e. the original purpose of the hot plate. It is also disadvantageous that the rotary switches are subject to wear and, thus, represent expendable material.

Further, it is known from the prior art to provide the touch-sensitive operating elements at or directly underneath the stove top surface, in which case a corresponding adjustment of the respective cooking areas can be made by touching the operating elements. Again, the touch-sensitive operating elements are connected to an electronic system which executes the hob adjustment made via the operating element. Although this form of operating elements has the advantage of being subject to virtually no wear, they do have the disadvantage, however, that these operating elements also occupy a certain space on the stove top surface, which space is then no longer available for cooking.

It is further known to position operating elements at a distance from the hot plate. While this does not reduce the space available for cooking on the hot plate, these operating elements require complex cabling to the stove's control unit.

Operating elements which transmit the switch positions or settings of the operating elements to the stove's control unit are also known. This has the disadvantage that a separate power supply needs to be provided for the operating elements. Another disadvantage is that the stove can be operated by the operating element even if the operating element is not located near the stove. For instance, the stove can be switched on from another room, which is disadvantageous, in particular, if the stove is switched on unintentionally.

Washing machines or the like generally have operating panels arranged at the front of the machine. In other embodiments, the operating panels are arranged in the upper end region of a lid, for example in dish washers, so that the operating panel is not visible from the outside in the closed state of the device.

The prior art operating panels or operating units have the disadvantage that the setting options of the device are limited by the preset setting options of the operating panel or operating unit. Refitting of the device is possible only at high financial expenditure.

### OBJECT OF THE INVENTION

Therefore, it is an object of the invention to provide an operating unit and an operating panel for operation of household appliances, especially for operation of a hob, a washing machine or the like, allowing to expand or adjust the range of functions of a household appliance in a simple and, in particular, inexpensive manner.

### SOLUTION ACCORDING TO THE INVENTION

The above object is achieved by the subject matters according to the claims. Advantageous embodiments are indicated in the dependent claims.

Accordingly, an operating plate, an operating panel, and a receiving device are provided.

The operating plate for operation of a household appliance may comprise an electrically conductive plate with at least one operating element arranged at or in the plate wherein the operating element comprises at least one first electrode and at least one second electrode, the at least one second electrode constitutes a coupling capacitance with ground, the at least one first electrode may be capacitively coupled with the electrically conductive plate, operation of the operating element may be capacitively transmitted to a receiving device, and whereby a load of the receiving device corresponds to the ground-coupling capacitance of the at least one second electrode.

The operating element may comprise at least one modulation device, whereby the combination of the at least one first electrode, the at least one second electrode and the modulation device constitutes an electrode device.

The operating element is preferably provided such that a change in the ground-coupling capacitance of the second electrode causes a change in the load of the receiving device.

An alternating electric field coupled into the conductive plate may be coupled at least partially into the first electrode of the electrode device, and the modulation device is designed to modulate an electric variable of the electrode device, preferably the impedance between the first electrode and the second electrode, depending on the change in the second electrode's ground-coupling capacitance.

The modulation may comprise an amplitude modulation.

The modulation device may include a resonant circuit and/or a frequency divider.

Each electrode device is preferably designed to cause a frequency modulation of the electric variable, preferably of the impedance between the first electrode and the second electrode, i.e. a modification of the electric variable with a certain frequency, the frequency modulation being indicative of the respective electrode device.

An electric field emitted by the receiving device may be coupled into the electrically conductive plate, and a modulation of the electric variable of the electrode device causes a change in the load at the receiving device.

The electrically conductive plate may comprise two segments, which are separated from each other by an insulator, the at least one first electrode of the operating element being arranged at a first segment, the at least one second electrode of the operating element being arranged at a second segment, and one of the two segments being coupled with ground.

An insulator is preferably provided between the electrically conductive plate and the least one operating element.

The operating panel may comprise a number of operating elements; whereby the operating elements are approach-sensitive and the operating panel is exchangeable.

The individual operating elements of the operating panel may be optically coupled with a control unit of the household appliance by a respective light guide. Any active elements can be visualized by colored light. All present operating elements may be illuminated using white light for background illumination.

The operating elements of the operating panel may also be capacitively coupled with the control unit of the household appliance so as to transmit a signal to the control unit.

It is advantageous for the operating elements to have an approach-sensitive design on a capacitive basis.

In this case, a operating element may comprise at least one first electrode, which is part of a first electrode device, the first electrode device being formed by the at least one first electrode and by at least one second electrode, and the first electrode device may be coupled with a modulation device.

The first electrode device may be coupled with an evaluating circuit, also referred to as a server circuit or receiving device. The coupling may be a capacitive coupling.

An electric field (alternating electric field) emitted by the evaluating circuit may be coupled into the second electrode of the first electrode device, in which case the coupled-in electric field may be modulated by the modulation device, the modulated signal may be fed back by the second electrode device, preferably by means of load modulation, to the evaluating circuit, and the feedback signal may be detected and evaluated by the evaluating circuit. The load change is detected by the evaluating circuit.

Preferably, an object (e.g. a hand) approaching the first electrode of the first electrode device may cause a modulation, preferably an amplitude modulation of the coupled-in electric field by the modulation device.

In an operating panel comprising several operating elements, the operating elements are preferably designed to be distinguishable by the evaluating circuit, in particular when an object approaches the operating element.

The evaluating circuit may be coupled with the control unit of the washing machine so as to transmit information regarding the activated and/or selected operating elements.

The receiving device (also referred to as server circuit or evaluating circuit), which is designed to cooperate with an operating plate and/or operating panel, may comprise: an electric circuit for generating an electric field (alternating electric field), which may be coupled into the operating plate and/or operating panel, and means for evaluating an electric variable of the electric circuit.

The evaluation may comprise detection of a load change in the electric circuit.

The load change may comprise at least one frequency-modulated part, and the evaluation comprises a separation of the frequency-modulated parts of the load change.

In an advantageous embodiment, the evaluating circuit may comprise:

an LC resonant circuit with a signal generating circuit, preferably a LC resonant circuit having a high quality-factor, for the generation of an electric field; and

a second electrode device, switched in parallel with the LC resonant circuit, the capacitance of the second electrode device constituting a part of the resonant circuit capacitance, and the electric field generated by the LC resonant circuit may be emitted by the second electrode device.

The evaluating circuit may also include an evaluating device, which detects the load impedance and/or the load change in the evaluating circuit.

The receiving device may comprise means by which a device to be operated is adjusted in accordance with an operation of the at least one operating element.

### SHORT DESCRIPTION OF THE FIGURES

Further details and features of the invention result from the following descriptions in connection with the drawing wherein:

FIG. 1 shows an operating unit according to the invention for use with a stove;

FIG. 2 shows a view from above of an operating unit according to the invention for use with a stove;

FIG. 3 shows a possible embodiment of an operating plate;

FIG. 4 shows a possible circuit diagram with a server circuit (receiving device) and a client circuit (operating element), in which the server circuit is arranged at the device to be operated (stove) and the client circuit (or several client circuits) are arranged at or in an operating plate, and the server circuit and the client circuit together form the operating unit according to the invention.

FIG. 5 shows a lateral sectional view of an upper front part of a household appliance;

FIG. 6 shows an embodiment of a household appliance in the closed state and in the open state, with an operating panel according to the invention;

FIG. 7 shows an embodiment of an operating panel according to the invention, and

FIG. 8 shows a sensor device, which is part of an operating panel comprising several sensor devices.

### DETAILED DESCRIPTION OF THE INVENTION

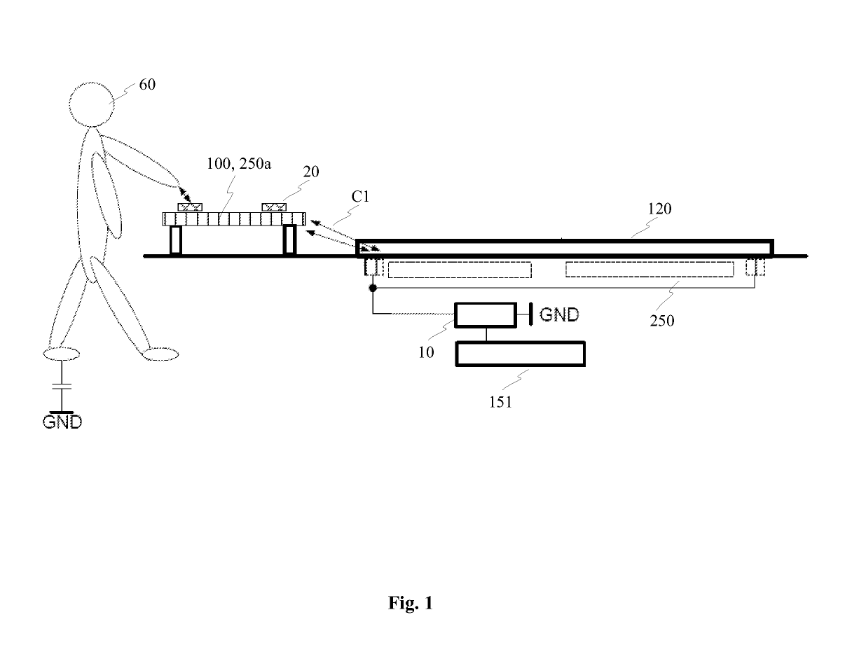

FIG. 1 shows an embodiment of a possible arrangement of an operating unit according to the invention for use with a stove or a hot plate 120.

The operating unit substantially comprises an operating plate 100 on which several operating elements 20 are arranged. The number of operating elements 20 provided depends substantially on the adjusting possibilities of the stove. The operating plate 100 is formed at least partially from an electrically conductive material. In the following, a conductive material or a conductive plate is always understood to mean an electrically conductive material or an electrically conductive plate, respectively. For example, a conductive plate may be enclosed in an acrylic housing or any other plastic housing so that the conductive plate is not visible. For instance, the operating plate can also be dishwasher-safe. However, the operating plate 100 should comprise a conductive material at least in those places where the individual operating elements will be arranged.

In one embodiment, as is evident from FIG. 1, the operating elements can be arranged at the surface of the operating plate 100. The arrangement of the operating elements 20 preferably takes place where the operating plate comprises a conductive plate. The operating elements 20 can also be arranged so as to be displaceable and/or detachable, so that the operating elements 20 are also easy to clean and stow.

In another embodiment, the operating elements 20 may be part of the operating plate 100, i.e. the operating elements 20 may be incorporated into the operating plate 100. Again, it is preferable to ensure that the operating elements 20 are arranged in the operating plate 100 in such a way that they are located in the area of the conductive plate. Thus, an operating plate 100 can be provided which is easy to clean and can, in particular, be stowed out of reach of children.

In particular, the operating plate 100 can be freely positioned and displaced next to, in front of, or behind the stove. Vertical or inclined placement of the operating plate 100 behind the stove is also possible, in particular when the operating elements 20 are part of the operating plate 100. In this way, a large degree of freedom is achieved with respect to the arrangement of the operating plate 100 or the operating elements 20, respectively.

The operating unit additionally comprises one or more server electrodes 250, which are preferably arranged on one or more sides of the hot plate 120. The server electrodes 250 may be arranged such that they are substantially not visible from the outside and, thus, do not impair the aesthetic appearance of the hot plate. The server electrodes 250 are connected with a server or a server circuit 10, respectively. In the following, the server circuit 10 is also referred to as receiving device or evaluating circuit, with the functionality respectively being the same.

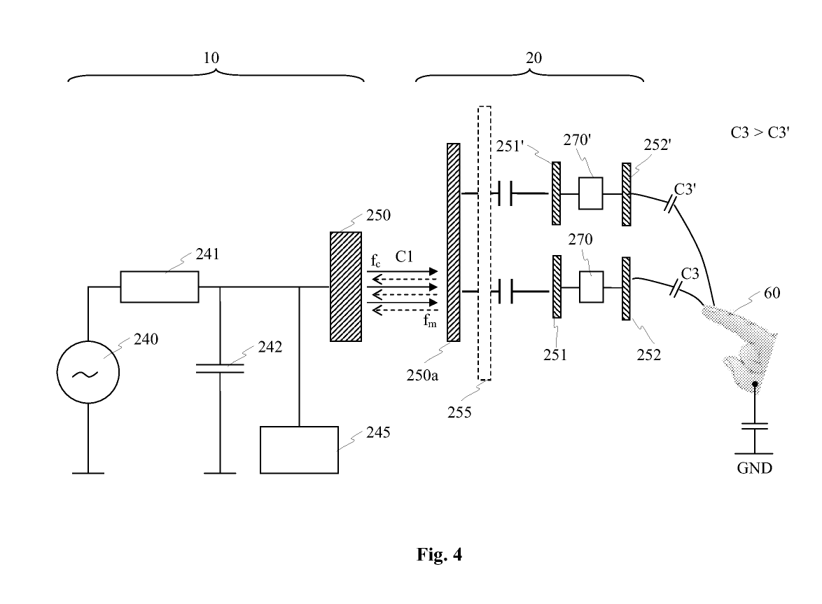

The basic functional principle of the operating unit according to the invention is explained in the following in connection with FIG. 1. A detailed functional description is then given below in connection with FIG. 4.

The server 10 is designed such that it can generate an alternating electric field, which can be emitted, or is emitted, at the server electrode 250. This alternating electric field is coupled into the operating plate 100 that is arranged next to the stove (or at the conductive plate of the operating plate 100, respectively). The function of the operating unit merely requires the latter to be located in the area of the emitted alternating field, so that coupling of the alternating field into the operating plate 100 is possible.

The operating elements 20 substantially comprise two electrodes 251, 252 and a modulation device. The modulation device is coupled with the two electrodes.

When the operating elements 20 are arranged at the operating plate 100, a capacitive coupling exists between a lower electrode 251 of the operating elements 20 and the conductive plate of the operating plate 100. When an operator's finger approaches or touches the upper electrode 252, a capacitative coupling forms between the upper electrode and ground.

The alternating electric field coupled into the operating plate 100 (250a) is first coupled into the lower electrode 251 of the operating element 20. The alternating electric field coupled into the operating element 20 can be rectified and thus be used for the power supply of the operating elements 20. Thus, the operating elements 20 do not need their own power supply, because they can draw the necessary power from the alternating electric field.

The modulation device arranged between the electrodes 251 and 252 is designed such that it modulates, preferably amplitude-modulates, a load of the server when a finger 60 approaches or touches the upper electrode. This load change at the server can be detected by an evaluating device of the server. The server and/or the operating elements 20 are designed such that the actuation of various operating elements 20 is distinguishable by the evaluating device. The evaluating device can thus detect the actuation of various operating elements 20 and can perform an adjustment of the hot plate or of the stove 120, respectively, in accordance with the actuated operating element 20. The result of the evaluation by the evaluating device can also be transmitted to a control unit 151, which then performs the corresponding adjustment.

The operating unit according to the invention has the advantage that the operating plate 100 is operable without an internal power supply. Moreover, no galvanic connection needs to be provided in order to connect the operating plate 100 with the stove electronics, since the transmission of the operation information from the operating elements 20 to the server electronics or to the server 10, respectively, is performed in a capacitive manner due to the operating elements 20 being designed to modulate the load of the server, and this modulation is detectable by the server.

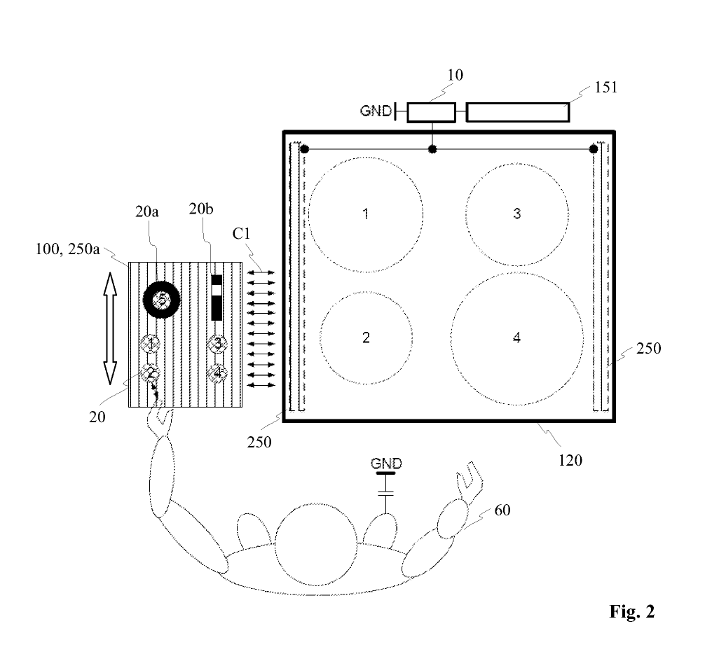

FIG. 2 shows the cooking plate 120 shown in FIG. 1 and the operating plate 100 from above. In this embodiment, two server electrodes 250, which extend over the entire edge length of the cooking plate, are arranged on the right and on the left side of the cooking plate 120, respectively. Both server electrodes are coupled with the server circuit or the server 10, respectively, so that one of the servers 10 can carry out both the power supply of the operating elements 20 and the evaluation of the operation of the operating elements 20, regardless of what side of the hob 120 the operating plate 100 is placed on, standing up or lying down.

In this example, the entire operating plate 100 is designed to be conductive. The operating elements 20 can therefore be arranged anywhere at the operating plate 100 (on the plate or integrated into the plate).

Operating elements 20 of the most diverse types can be provided. One example are simple operating elements 20, which are provided only for “touching” are provided, for example ON/OFF switches.

Another example would be a rotary switch 20a. In order to allow a rotary switch to be realized with different switching states, it is necessary to provide an area on the operating plate 100 that is especially reserved for this requirement. One possibility is to provide a rotary switch with a rotor electrode and a stator electrode wherein the stator electrode is part of the operating plate 100, but is not connected with the conductive plate of the operating plate 100. The operating plate 100 can be designed here such that the alternating electric field coupled into the operating plate 100 by the server electrode 250 can be coupled into the stator electrode of the rotary switch. Different rotary positions of the rotor electrode relative to the stator electrode then have an effect on the modulation of the server's load.

Another example would be a slide switch 20b. This slide switch can be formed from several operating elements 20 arranged side by side. Another embodiment consists in providing a slide switch with a rotor electrode and a stator electrode, as in the case of the rotary switch, and when the position of the rotor electrode relative to the stator electrode changes, the server's load changes accordingly. Again, the stator electrode should not be connected with the conductive plate of the operating plate 100.

Other forms of operating elements 20 are possible. Depending on the requirements, corresponding electrodes can be provided, as in the case of the rotary switch or of the slide switch, or the evaluation unit of the server 10 can be suitably adapted. For example, a finger pressing on an operating element 20 for a long time can cause a fast increase in the temperature setting.

If the operating plate 100 is located at a sufficient distance from the hob, so that no coupling can take place between the server electrode 250 and the operating plate 100, the operating plate 100 cannot be inadvertently used for operation of the hob. This enables efficient protection of children.

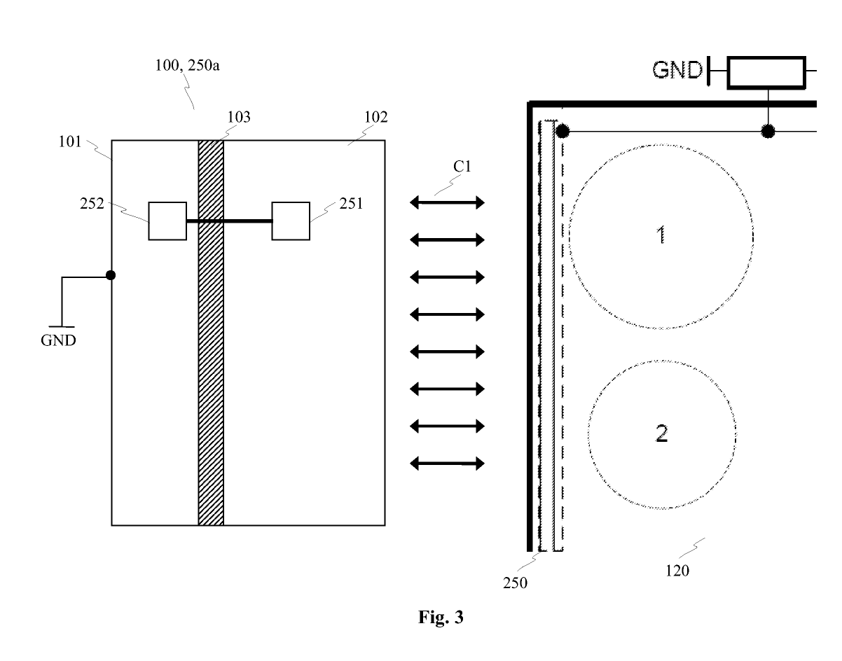

FIG. 3 shows a specific embodiment of an operating plate 100. The operating plate 100 consists of two (electrically conductive) segments 101 and 102, which segments are not connected with each other in a conducting manner 103. In this case, the segment 101 comprises a predetermined coupling with ground.

On this operating plate 100, the operating elements 20 are arranged in a specific way as far as their electrodes are concerned. As shown above, the operating elements 20 comprise two electrodes 251 and 252. The electrode 252 is arranged here on the segment 101, which is coupled with ground. The second electrode 251 is arranged on the other segment 102 of the operating plate 100. Since the segment 101 is capacitatively coupled with ground, it is also coupled with ground by the electrodes 251 and 252.

This results in an always present basic coupling of the operating elements 20 to ground, as soon as the operating plate 100 is located in the area of the electric field emitted by the server electrode. This existing slight basic coupling to ground has the effect that each modulation device 270 of the operating elements 20 continuously modulates the server's load with a certain (low) amplitude. This allows the server to detect that the necessary operating elements 20 are located in the server field. Moreover, the server can detect failure of individual operating elements 20, since these then no longer cause changes in the server's load. Additionally, this low basic coupling can also be used to recognize when the operating plate 100 moves out of the server field. The stove or the stove electronics, respectively, or the server can then automatically switch off the stove, for example, after a certain time.

Moreover, the operating plate 100 may also be designed such that an insulator 255 (cf. FIG. 4) is provided between the operating elements 20 and the conductive plate. This allows the sensitivity of the operating elements 20 or of the server circuit 10, respectively, to be increased.

FIG. 4 shows an embodiment (as an equivalent circuit diagram) of an operating unit. The operating elements 20 are referred to in the following as client or as client circuit.

The server circuit 10 consists substantially of a generator 240 and an LC resonant circuit constituted by an inductance 241 and a capacitance 242. The LC resonant circuit can be formed as a serial resonant circuit or as a parallel resonant circuit. A server electrode 250 as well as an evaluating device 245 are located parallel to the LC resonant circuit.

The generator 240 of the server circuit first generates an alternating voltage, which is fed to the LC resonant circuit 241, 242, in order to subsequently generate an electric field with a sufficiently large range. The generated electric field fc is emitted at the server electrode 250 and is coupled into the electrode 250a (which corresponds to the electrically conductive plate) of the client circuit 20.

The client circuit 20 consists substantially of an electrode device with two electrodes 251 and 252, a modulation device 270, and the electrodes 251, 252 are each coupled with the modulation device 270. The electrodes 251 thus form the above-mentioned and described lower electrode of the operating element 20.

By coupling the electric field into the conductive plate 250a, the client circuit is also supplied with energy at the same time.

The arrangement of the server electrode 250 with respect to the conductive plate 250a is to be selected in such a way that the electric field emitted by the server electrode can be coupled into the conductive plate 250a.

The electric field fc generated by the server circuit 10 and emitted by the server electrode 250 is coupled into the conductive plate 250a of the client circuit and is further coupled into the electrode 251 by means of capacitive coupling. The load of the server circuit is amplitude-modulated by the modulation device 270 via the coupled-in electric field fc. This modulation is detectable by the server circuit.

The load modulation performed by the modulation device 270 of the client circuit is evaluated by the evaluating device 245.

A hand or a finger 60 approaching the second electrode 252 (the upper electrode of the operating element) of the client circuit 20, as shown in FIG. 4, causes the coupling capacity C3 to change, so that the level at which the load is being modulated changes, which leads to a changed amplitude of the load.

According to the embodiment shown in FIG. 1 and FIG. 2, the operating unit can comprise several operating elements 20, i.e. several client circuits (251, 270, 252, and 251′, 270′, 252), which are operated by the electric field of the server circuit (i.e. by one single server circuit). Therefore, the evaluating device 245 should be designed in a way allowing to distinguish the amplitude modulations of the load by the two client circuits.

That is, the individual client circuits are designed such that the evaluation unit of the server circuit can separate the load, which has been amplitude-modulated by the client circuits, and can accordingly assign it to the individual client circuits. For this purpose, different measures can be taken on the side of the client circuits.

For example, the individual client circuits can comprise a free-running oscillator, each oscillator being operated at a different oscillator frequency, thus applying to the server circuit (in case of several client circuits) a frequency mixture with different amplitudes, which can be separated accordingly, e.g. with the help of a Fourier transformation.

Instead of a free-running oscillator, the client circuits can also be provided with a frequency divider, which divides the frequency of the electric field emitted by the server circuit. The division ratio preferably differs in the individual client circuits, so that the individual client circuits each work with a different frequency and amplitude-modulate the load of the server circuit with a different frequency in each case. Again, a frequency mixture with different amplitudes is detected at the server circuit (in case of several client circuits), and the mixture can be separated accordingly, e.g. with the help of a Fourier transformation.

The server circuit or the evaluation unit 245, respectively, can be coupled with a control unit or a device control 151, respectively.

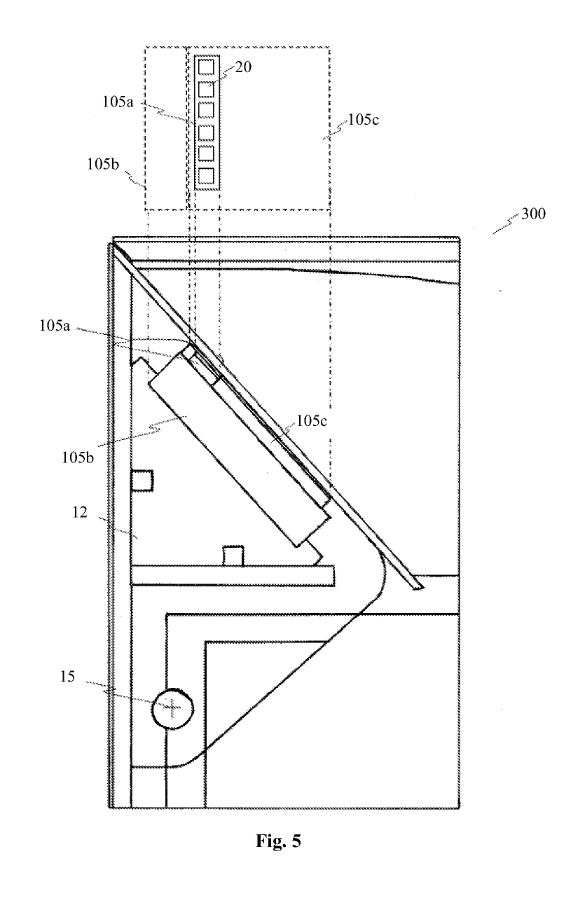

FIG. 5 shows a side sectional view of an upper front part of a household appliance 300. In the embodiment according to FIG. 5, the upper front part is provided with an apparatus 12 that can be forwardly folded out. Folding out the apparatus 12 enables free access to an operating panel (105a 105b, 105b, 105c). In the open state, adjustments of various device parameters (such as the temperature of a dishwasher, or the washing program of a washing machine) can be made by a visible component 105a of the operating panel. After closing the foldout apparatus, the device can automatically start or can be started externally, if necessary.

The upper part of FIG. 5 shows the operating panel (105a 105b, 105b, 105c) in a top view in the closed state of the foldout apparatus 12. In the open state, only the operating component 105a is visible from the outside, while the other components 105b and 105c of the operating panel are not visible from the outside. These components 105b 105c, 105c are preferably hidden beneath the surface.

In a particularly advantageous embodiment of the invention, the operating component 105a is detachable. This (together with a corresponding configuration of the components 105b and 105c) makes it possible to change the range of functions of the device or to upgrade the device by simply exchanging the operating component. A simple operating component 105a for a washing machine can provide, for example, 8 different settings for the washing machine, whereas a luxury variant of the operating component 105a provides, for example, 20 possible settings. Thus, a washing machine can be upgraded from a simple version to a luxury version merely by exchanging the operating component 105a.

Another advantage of the invention is that a uniform basic device can be provided for different design variants, which can, for example, considerably reduce production costs, because there is no need to produce different models of a device.

While the operating component 105a is exchangeable, the components 105b and 105c are preferably incorporated permanently into the instrument. In this case, the component 105b can be a is server or control device, respectively, which is coupled with the operating component 105 after insertion of the latter.

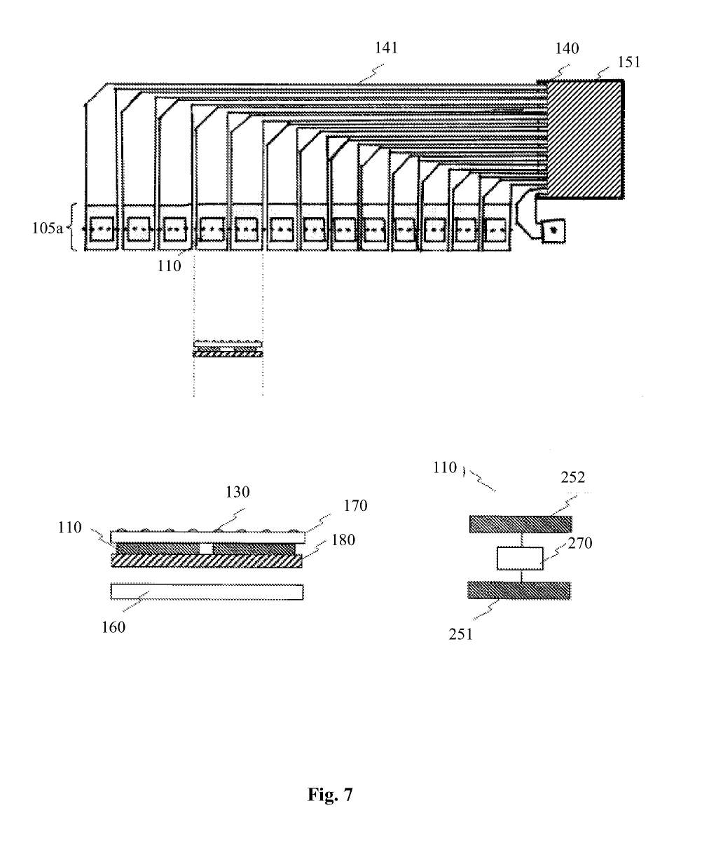

In one embodiment, the component 105c can comprise a light guide plate, which is coupled with a server unit equipped with light-emitting diodes for coupling light into the light guides. An embodiment for this purpose is described in more detail below with reference to FIG. 7.

The surface of the operating component 105a is preferably covered with a transparent panel in order to prevent the operating component from being soiled or damaged. This panel may be part of the cover, under which the entire operating panel 105a 105b, 105b, 105c is located. The surface of the transparent panel may comprise small knobs, for example, providing tactile feedback to the user.

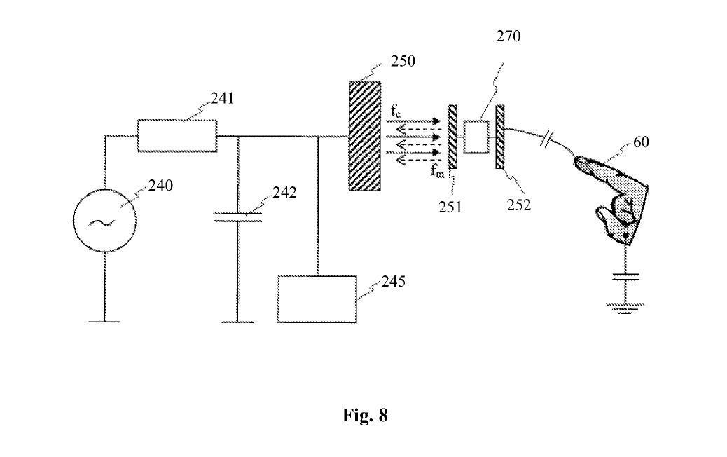

In a particularly advantageous embodiment of the invention, the operating component 105a comprises a number of operating elements 20, and each operating element can have a function assigned to it. An approach-sensitive design of the operating elements 20 is particularly advantageous, since the operating elements 20 are preferably located behind a transparent panel. The function of the approach-sensitive operating elements 20 is explained in more detail in connection with FIG. 8.

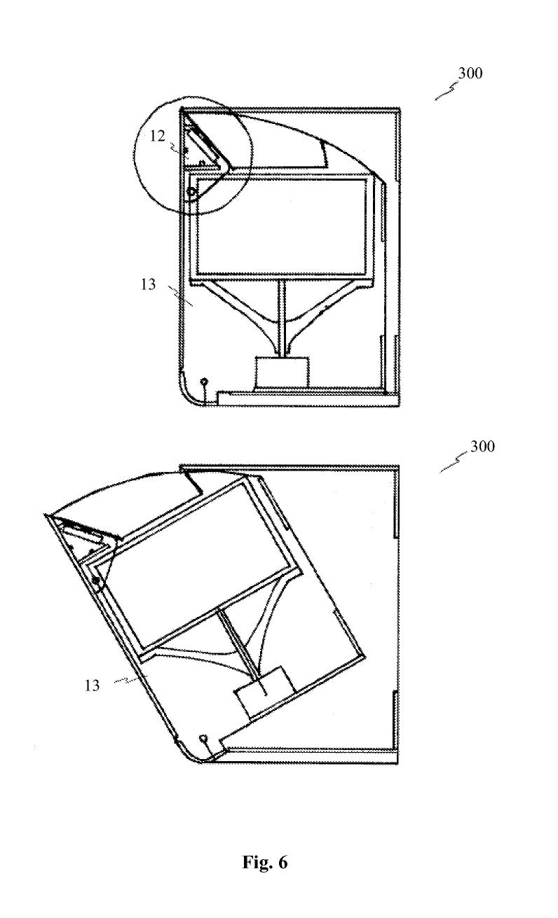

FIG. 6 shows a household appliance (in this case, a washing machine) in the closed state (upper representation) and in the open state (lower representation) in a side sectional view. The area shown in the circle in the upper representation is was described in more detail already, in an enlarged view, in connection with FIG. 5. Additionally or as an alternative to the foldout apparatus 12, the entire loading device 13 for loading the laundry can also have a foldout design. In the opened state of the loading device 13, the washing machine can be loaded from above. At the same time, access to the operating panel 105a 105b, 105b, 105c, in particular access to the operating component 105a, is enabled so that the device settings can be carried out as well.

In an alternative embodiment of a household appliance, not shown here, the operating component 105a can also be arranged on the household appliance in such a way that the settings of the device can be made externally, while the other two components 105b and 105c of the operating panel can be arranged in the lid of the device such that they are not visible. In this embodiment, too, the operating component 105a is exchangeable.

FIG. 7 shows an embodiment of an operating panel according to the invention, consisting of a control unit 151, a light guide plate 141, and a operating component 105a.

Several light-emitting diodes, which can preferably emit light of different colors, are arranged at the control unit 151, which is an integral part of the household appliance. The light emitted by the light-emitting diodes is coupled into the respective light guides of the light guide plate 141 that are assigned to the light-emitting diodes. The light coupled in is transmitted to the operating component 105a, where it can illuminate the operating elements arranged on the operating component.

In one embodiment, the light-emitting diodes 140 can normally emit white light, so that all operating elements are irradiated with a white background light. When actuating a operating element, i.e. when selecting a device function or a device setting (e.g. the water temperature), the corresponding light-emitting diode assigned to the operating element can emit green light, for example. When a malfunction occurs, red light can be coupled in, for example.

In one embodiment of the invention, the light guide plate 141 and the operating component 105a are arranged on a base plate. This will allow the base plate to be removed from the household appliance and to be replaced with another base plate.

FIG. 7 shows a control unit 151 on which 14 light-emitting diodes are arranged. This allows a household appliance to be provided with a operating component comprising up to 14 operating elements. In the area of the coupling location with the control unit 151, the light guide plate 141 can be designed such that only corresponding functionalities of the control unit are enabled or activated, respectively, when a corresponding light guide unit is present on the light guide plate 141.

For example, if light guide units are present only for the first four light-emitting diodes, the functionality of the other ten operating elements can be deactivated.

In another embodiment, only the operating component 105a may be exchangeable. Again, activation of the corresponding functions can be performed depending on the operating elements that are present, for example using a connecting unit, and the connecting unit causes the corresponding functions to be enabled once the operating component 105a has been exchanged.

The light guides can be formed from an acrylic material or any other material that is suitable to transmit light.

The operating component 105a is preferably located behind a transparent cover plate, while the light guide units coupled with the operating elements, or the light guide plate 141, respectively, are hidden behind a cover plate.

The lower left area of FIG. 7 shows a detail of the operating component 105a in a frontal view.

First of all, the operating component comprises an upper, transparent end plate 170. Several knobs 130 may be provided for improved tactility during operation.

Under the end plate 170 is provided a plate accommodating the operating elements 110. The plate preferably consists of the same material as the end plate 170, so that the light exiting from the light guides can be coupled into the end plate 170 again. In this case, the individual areas of the operating component 105a, or the plate housing the operating elements are optically separated from one another.

A conductive plate 180, on which the plate housing the operating elements as well as the operating elements themselves are mounted, is provided below the plate housing the operating elements. This plate 180, together with the elements mounted thereon, thus constitutes that part of the operating component 105a which can be removed from the household appliance and can be replaced by another one.

An electrode 160, which extends preferably over the entire area of the operating component 105a, is arranged beneath the operating component 105a (by galvanic or capacitive coupling). This electrode, referred to as the server electrode, is provided with an evaluating circuit, referred to as the server circuit. In this case, the selection of a operating element by the evaluating circuit is detected on the basis of electric field interactions between the operating element and the server electrode.

A operating element 110 that is suitably designed for this purpose is shown at bottom right in FIG. 7. The operating element substantially consists of two electrodes 251, 252 and of a modulation device 270. The basic function is the following: an electric field, which is emitted by the server electrode and is coupled into the lower of the two electrodes, is modulated by the modulation device. The modulation is fed back to the server circuit by means of load modulation and can be detected by the server circuit.

This embodiment of a operating element 110 allows to determine the availability of a certain functionality solely by the presence of a operating element.

FIG. 8 shows an embodiment (basic circuit) of a sensor device (operating element 110 and server circuit).

The sensor device consists of a server circuit (240, 241, 242, 245, 250) and of a client circuit (251, 252, 270). The client circuit is identified by the reference numeral 110 in FIG. 7.

The server circuit consists substantially of a generator 240 and an LC resonant circuit formed by the inductance 241 and the capacitance 242. The LC resonant circuit can be provided as a serial resonant circuit or as a parallel resonant circuit. A server electrode 250 as well as an evaluating device 245 are arranged in parallel to the LC resonant circuit. The server electrode 250 is identified by the reference numeral 160 in FIG. 7.

The functionality of the server circuit is substantially the same as already explained with reference to FIG. 4. The generator 240 of the server circuit first generates an alternating voltage that is fed to the LC resonant circuit 241, 242 in order to subsequently generate an electric field with a sufficiently large range. The generated electric field fc is emitted at an electrode 250 and is coupled into the electrode 251 of the client circuit. By coupling the electric field into the electrode 251, the client circuit is also supplied with energy at the same time, so that a power supply for the client circuits can be dispensed with, which is particularly advantageous for integration of the client circuit into the operating component 105a.

In this case, the electrode 250 is arranged in a substantially planar manner below the electrodes 251. The arrangement and design of the electrode 250 is selected such that the electric field emitted by the electrode 250 can be coupled into all the electrodes 251 of the client circuits 110.

The client circuit (251, 252, 270) consists substantially of an electrode device with two electrodes 251 and 252 as well as a modulation device 270, and the electrodes 251, 252 are each coupled with the modulation device 270.

The electric field fc generated by the server circuit and emitted by the server electrode 250 is coupled into the first electrode 251 of the client circuit. The electric field fc coupled in is modulated by the modulation device 270. The modulated signal fm is fed back via the server electrode 250, preferably by load modulation, to the server circuit where it can be detected by the evaluating device 245.

The signal modulation performed by the modulation device 270 of the client circuit is evaluated by the evaluating device 240. The electric field is amplitude-modulated by the client circuit or the modulation device 270, respectively.

A hand or a finger 60 approaching the second electrode 252 of the client circuit 110, as shown in FIG. 8, causes a change in the level of the modulation device, which leads to a changed amplitude of the modulated electric field. This change in amplitude is detected and evaluated by the evaluating device 245.

Since, according to the present embodiment (as shown in FIG. 7), several client circuits 110 can be operated by the electric field of a server circuit and since an evaluating device is responsible for evaluation of the approaches to the electrodes 252 of the several client circuits, the evaluating device 245 must be in a position to distinguish the individual client circuits from one another.

That is, the individual client circuits are designed such that the evaluation unit of the server circuit can separate the signal, which has been amplitude-modulated by the client circuits, and can accordingly assign it to the individual client circuits. For this purpose, different measures can be taken on the side of the client circuits.

For example, the individual client circuits can comprise a free-running oscillator, each oscillator being operated at a different oscillator frequency, thus applying to the server circuit (in case of several client circuits) a frequency mixture with different amplitudes, which can be separated accordingly, e.g. with the help of a Fourier transform.

Instead of a free-running oscillator, it is also possible to provide a frequency divider, which divides the frequency of the server circuit's signal. The division ratio preferably differs in the individual client circuits, so that the individual client circuits each work with a different frequency and amplitude-modulate the alternating field of the server circuit with a different frequency.

Another alternative consists in providing a timing element. This has the effect that only one client circuit is active when the timing elements are suitably set. Also, the client circuits are preferably activated cyclically after one another.

The server circuit or the evaluation unit 245, respectively, can be coupled with the control unit 151, in which case the evaluation unit 245 provides corresponding information to the control unit via the selected operating element.

This embodiment makes it possible to upgrade or downgrade, respectively, the functionality of a household appliance merely by the presence of operating elements, realized on a capacitive basis, by adding or omitting client circuits. The particularly simple structure of the client circuit allows to realize an exchangeable operating component in a particularly cost-effective manner.

A further advantage of operating elements on a capacitive basis (since the client circuits are approach-sensitive) is that they are safely arranged behind a panel 170. Pushbuttons, which can be additionally subject to wear, can be dispensed with.

1. An operating plate for operation of a household appliance, comprising an electrically conductive plate with at least one operating element arranged at or in the plate,
wherein the operating element comprises at least one first electrode and at least one second electrode,
wherein the at least one second electrode constitutes a coupling capacitance with ground,
wherein the at least one first electrode is capacitively couplable with the electric conductive plate,
wherein operation of the operating element is capacitively transmitted to a receiving device, and
wherein a load of the receiving device corresponds to the ground-coupling capacitance of the at least one second electrode.

2. The operating plate according to claim 1 wherein the operating element comprises at least one modulation device, and the combination of the at least one first electrode, the at least one second electrode and the modulation device constitutes an electrode device.

3. The operating plate according to claim 1 wherein the operating element is provided such that a change in the ground-coupling capacitance of the second electrode causes a change in the load of the receiving device.

4. The operating plate according to claim 1 wherein an alternating electric field coupled into the conductive plate is couplable at least partially into the first electrode of the electrode device and the modulation device is designed to modulate an electric variable of the electrode device, depending on the change in the coupling capacity of the second electrode with ground.

5. The operating plate according to claim 4 wherein the modulation comprises an amplitude modulation.

6. The operating plate according to claim 2 wherein the modulation device comprises one of a resonant circuit and a frequency divider.

7. The operating plate according to claim 1 wherein each electrode device is designed to cause a frequency modulation of the electric variable, the frequency modulation being indicative of the respective electrode device.

8. The operating plate according to claim 1 wherein an electric field emitted by the receiving device is couplable into the electrically conductive plate and a modulation of the electric variable of the electrode device causes a change in the load at the receiving device.

9. The operating plate according to claim 1 wherein the electrically conductive plate comprises two segments, which are separated from each other by an insulator, the at least one first electrode of the operating element being arranged at a first segment, the at least one second electrode of the operating element being arranged at a second segment, and one of the two segments being coupled with ground.

10. The operating plate according to claim 1 wherein an insulator is provided between the electric conductive plate and the least one operating element.

11. An operating panel for a household appliance, the panel comprising a number of operating elements wherein the operating elements are approach-sensitive and the operating panel is exchangeable.

12. The operating panel according to claim 11 wherein the individual operating elements of the operating panel are optically coupled with a control unit of the household appliance by a respective light guide.

13. The operating panel according to claim 11 wherein the operating elements of the operating panel is couplable with the control unit of the household appliance so as to transmit a signal to the control unit.

14. The operating panel according to claim 11 wherein a operating element comprises at least one first electrode, which is part of a first electrode device, the first electrode device being formed by the at least one first electrode and by at least one second electrode, and the first electrode device is couplable with a modulation device.

15. The operating panel according to claim 14 wherein the first electrode device is capacitively couplable with an evaluating circuit.

16. The operating panel according to claim 15 wherein an electric field emitted by an evaluating circuit is couplable into the second electrode of the first electrode device, the coupled-in electric field is modulated by the modulation device, the modulated signal is fed back by the second electrode device, preferably by means of load modulation, to the evaluating circuit, and the feedback signal is detected and evaluated by the evaluating device.

17. The operating panel according to claim 16 wherein an object approaching the first electrode of the first electrode device causes a modulation, preferably an amplitude modulation of the coupled-in electric field by the modulation device.

18. The operating panel according to claim 14, comprising several operating elements, the operating elements being designed to be distinguishable by the evaluating device.

19. The operating panel according to claim 14 wherein the evaluating circuit is coupled with the control unit of the washing machine so as to transmit information regarding the activated and/or selected operating elements.

20. A household appliance, comprising an operating panel according to claim 11.

21. A receiving device, designed to cooperate with an operating plate according to claim 1, the receiving device comprising:
an electric circuit for generating an electric field, which is couplable into the operating plate and/or the operating panel, and means for evaluating an electric variable of the electric circuit.

22. The receiving device according to claim 21 wherein the evaluation comprises detection of a load change in the electric circuit.

23. The receiving device according to claim 22 wherein the load change comprises at least one frequency-modulated part and the evaluation comprises a separation of the frequency-modulated parts of the load change.

24. The receiving device according to claim 21 wherein the electric circuit comprises:
an LC resonant circuit with a signal generating circuit, preferably a LC resonant circuit having a high quality-factor, for the generation of the electric field, and
a second electrode device, connected in parallel with the LC resonant circuit wherein the capacitance of the electrode device constitutes a part of the resonant circuit capacitance of the LC resonant circuit and the electric field generated by the LC resonant circuit is emittable by the electrode device.

25. The receiving device according to claim 21, comprising means by which a device to be operated is adjusted in accordance with an operation of the at least one operating element.
